(19) United States
(12) Patent Application Publication
(10) Pub. No.: US 2025/0273282 A1
(43) Pub. Date: Aug. 28, 2025

(54) NON-VOLATILE MEMORY, SEMICONDUCTOR STORAGE DEVICE, AND NON-VOLATILE MEMORY CONTROL METHOD

(71) Applicant: SONY SEMICONDUCTOR SOLUTIONS CORPORATION, KANAGAWA (JP)

(72) Inventor: TAKURO KANEMURA, KANAGAWA (JP)

(21) Appl. No.: 18/858,445

(22) PCT Filed: Mar. 3, 2023
(86) PCT No.: PCT/JP2023/008006

§ 371 Date: Oct. 21, 2024

(30) Foreign Application Priority Data
Apr. 28, 2022 (JP) 2022-074303

(51) Int. Cl. G11C 16/34; G11C 16/04; G11C 16/10; G11C 16/26

(52) U.S. Cl. CPC G11C 16/3459; G11C 16/0483; G11C 16/102; G11C 16/26

(57) ABSTRACT

A decrease in life is curbed for a non-volatile memory that performs write processing again when writing fails.

A memory cell is inserted between a pair of signal lines. A write control circuit performs write processing of supplying a predetermined power supply voltage to one signal line corresponding to write data among the pair of signal lines, and write retry processing of bringing the pair of signal lines into a floating state in a case where verification data and the write data match, and supplying the power supply voltage to the signal line in a case where the verification data and the write data do not match. The reading circuit performs sense processing of reading data from the memory cell after the write processing and supplying the data as verification data to the write control circuit. A precharge circuit starts precharge processing of supplying an inhibition voltage different from a predetermined reference voltage to the pair of signal lines between the sense processing and the write retry processing.

### TECHNICAL FIELD

The present technology relates to a non-volatile memory. Specifically, the present invention relates to a non-volatile memory that performs verification processing at the time of writing, a semiconductor storage device, and a non-volatile memory control method.

### BACKGROUND ART

In recent information processing systems, a non-volatile memory (NVMV) may be used as an auxiliary storage device or a storage. This non-volatile memory is roughly divided into a flash memory compatible with data access in a large size unit and a non-volatile random access memory (non-volatile RAM: NVRAM) capable of high-speed random access in a small unit. Here, representative examples of the flash memory include a NAND flash memory. Meanwhile, examples of the non-volatile random access memory include a resistance RAM (ReRAM), a phase-change RAM (PCRAM), a magnetoresistive RAM (MRAM), and the like.

When data is written to the non-volatile memory described above, three-stage control including write processing of writing data, verification processing of determining whether or not the writing has succeeded, and write processing again when the writing fails may be performed in order to ensure reliability. For example, a write control method has been proposed in which write processing and verification processing are performed, and the write processing is performed again with a write pulse having a longer pulse width than the first write processing at the time of a write failure (see, for example, Patent Document 1).

### CITATION LIST

### Patent Document

Patent Document 1: Japanese Translation of PCT International Application Publication No. 2013-529350

### SUMMARY OF THE INVENTION

### Problems to be Solved by the Invention

In the above-described conventional technology, both improvement of reliability and reduction of power consumption are achieved by making the pulse width at the time of the second write processing longer than that at the time of the first write processing. However, in the above-described write control method, a write pulse having a long pulse width is also applied to the gate of a transistor in a memory cell in which writing is not performed at the time of the second write processing. For this reason, the voltage stress of the transistor that does not perform writing increases, and the life of the non-volatile memory may be reduced.

The present technology has been made in view of such a situation, and aims to curb a decrease in life of a non-volatile memory that performs write processing again when writing fails.

### Solutions to Problems

The present technology has been made to solve the above-described problem, and a first aspect thereof provides a non-volatile memory and a control method thereof, the non-volatile memory including: a memory cell inserted between a pair of signal lines; a write control circuit that performs write processing of supplying a predetermined power supply voltage to one signal line corresponding to write data among the pair of signal lines, and write retry processing of bringing the pair of signal lines into a floating state in a case where verification data and the write data match and supplying the power supply voltage to the signal line in a case where the verification data and the write data do not match; a reading circuit that performs sense processing of reading data from the memory cell after the write processing and supplying the data as the verification data to the write control circuit; and a precharge circuit that starts precharge processing of supplying an inhibition voltage different from a predetermined reference voltage to the pair of signal lines between the sense processing and the write retry processing. This brings about an effect that a decrease in the life of the non-volatile memory is curbed.

Furthermore, in the first aspect, the write control circuit may include a power supply side write control circuit and a ground side write control circuit; the power supply side write control circuit may include a first latch circuit that holds the write data, a second latch circuit that holds either the verification data or inverted data obtained by inverting the write data, and a write driver that causes the power supply voltage to be supplied to one of the pair of signal lines on the basis of data held in each of the first and second latch circuits; and the ground side write control circuit may include a column selector that connects another of the pair of signal lines and the reference voltage. This brings about an effect that a current flows through the memory cell.

Furthermore, in the first aspect, the ground side write control circuit may include: a third latch circuit that holds the write data; a fourth latch circuit that holds either the verification data or the inverted data; and a column selector that connects the another and the reference voltage on the basis of data held in each of the third and fourth latch circuits. This brings about an effect that the circuit scale is reduced.

Furthermore, in the first aspect, the write driver may generate a predetermined write enable signal on the basis of the data, and the ground side write control circuit may include a third latch circuit that holds the write data, and a column selector that connects the another and the reference voltage on the basis of the write data and the write enable signal. This brings about an effect that the number of latch circuits is reduced.

Furthermore, in the first aspect, the write control circuit may be disposed in each of a plurality of columns; the plurality of columns may be divided into a predetermined number of sharing units that share a sense line; and the reading circuit may supply the verification data via the sense line for each of the sharing units. This brings about an effect that the amount of wiring is reduced.

Furthermore, in the first aspect,
the write control circuit may perform verification processing again after the write retry processing, and perform the write retry processing again in a case where the verification data and the write data do not match and the number of executions of the verification processing has not reached a predetermined upper limit. This brings about an effect that the reliability of writing is improved.

Furthermore, in the first aspect, the precharge circuit may perform the precharge processing between the sense processing and the write retry processing. This brings about an effect that the supply period of the inhibition voltage is shortened.

Furthermore, in the first aspect, the precharge circuit may continue the precharge processing until the write retry processing ends. This brings about an effect that a voltage drop of the pair of signal lines is curbed.

Furthermore, in the first aspect, the memory cell may include a transistor and a resistive element connected in series between the pair of signal lines. This brings about an effect that the voltage stress of the transistor is reduced.

Furthermore, in the first aspect, a supply period of the power supply voltage during the write retry processing may be longer than a supply period of the power supply voltage during the write processing. This brings about an effect that reliability is improved.

Furthermore, a second aspect of the present technology provides a semiconductor storage device including: a memory cell inserted between a pair of signal lines; a write control circuit that performs write processing of supplying a predetermined power supply voltage to one signal line corresponding to write data among the pair of signal lines, and write retry processing of bringing the pair of signal lines into a floating state in a case where verification data and the write data match and supplying the power supply voltage to the signal line in a case where the verification data and the write data do not match; a reading circuit that performs sense processing of reading data from the memory cell after the write processing and supplying the data as the verification data to the write control circuit; a precharge circuit that starts precharge processing of supplying an inhibition voltage different from a predetermined reference voltage to the pair of signal lines between the sense processing and the write retry processing; and a memory controller that supplies the write data and causes the write processing to be executed. This brings about an effect that a decrease in the life of the semiconductor storage device is curbed.

### BRIEF DESCRIPTION OF DRAWINGS

FIG. 1 is a block diagram illustrating a configuration example of a semiconductor storage device of a first embodiment of the present technology.

FIG. 2 is a circuit diagram illustrating a configuration example of a memory cell array of the first embodiment of the present technology.

FIG. 3 is a block diagram illustrating a configuration example of a column driver of the first embodiment of the present technology.

FIG. 4 is a block diagram illustrating a configuration example of a power supply side write control circuit and a ground side write control circuit of the first embodiment of the present technology.

FIG. 5 is a timing chart illustrating a configuration example of an operation of a non-volatile memory of a column in which writing has succeeded in the first embodiment of the present technology.

FIG. 6 is a timing chart illustrating a configuration example of an operation of a non-volatile memory of a column in which writing has failed in the first embodiment of the present technology.

FIG. 7 is a diagram for describing voltages of a source line and a bit line during write processing in the first embodiment of the present technology.

FIG. 8 is a diagram for describing voltages of a source line and a bit line during precharge processing in the first embodiment of the present technology.

FIG. 9 is a diagram for describing voltages of a source line and a bit line during write retry processing of a column in which writing has succeeded in the first embodiment of the present technology.

FIG. 10 is a diagram for describing voltages of a source line and a bit line during write retry processing of a column in which writing has failed in the first embodiment of the present technology.

FIG. 11 is a flowchart illustrating an example of an operation of the non-volatile memory of the first embodiment of the present technology.

FIG. 12 is a flowchart illustrating an example of an operation of a non-volatile memory of a comparative example.

FIG. 13 is a block diagram illustrating a configuration example of a power supply side write control circuit and a precharge circuit of a modification of the first embodiment of the present technology.

FIG. 14 is a diagram for describing precharge processing for a column in which writing has succeeded in the modification of the first embodiment of the present technology.

FIG. 15 is a diagram for describing precharge processing for a column in which writing has failed in the modification of the first embodiment of the present technology.

FIG. 16 is a diagram illustrating a wiring example of the memory cell array of a second embodiment of the present technology.

FIG. 17 is a block diagram illustrating a configuration example of a column driver of a second embodiment of the present technology.

FIG. 18 is a block diagram illustrating a configuration example of a memory control unit 214 and a column driver of a third embodiment of the present technology.

FIG. 19 is a flowchart illustrating an example of an operation of a non-volatile memory of the third embodiment of the present technology.

FIG. 20 is a block diagram illustrating a configuration example of a column driver of a fourth embodiment of the present technology.

FIG. 21 is a block diagram illustrating a configuration example of a power supply side write control circuit and a ground side write control circuit of the fourth embodiment of the present technology.

FIG. 22 is a block diagram illustrating a schematic configuration example of a vehicle control system.

FIG. 23 is an explanatory diagram illustrating an example of installation positions of imaging sections.

### MODE FOR CARRYING OUT THE INVENTION

Hereinafter, modes for carrying out the present technology (hereinafter referred to as embodiments) will be described. The description will be given in the following order.
1. First embodiment (example of performing precharge immediately before write retry)
2. Second embodiment (example of performing burst connection and performing precharge immediately before write retry)
3. Third embodiment (example of performing verification up to upper limit and performing precharge immediately before write retry)
4. Fourth embodiment (example of reducing number of latch circuits and performing precharge immediately before write retry)
5. Examples of application to mobile body

### 1. First Embodiment

### [Configuration Example of Storage Device]

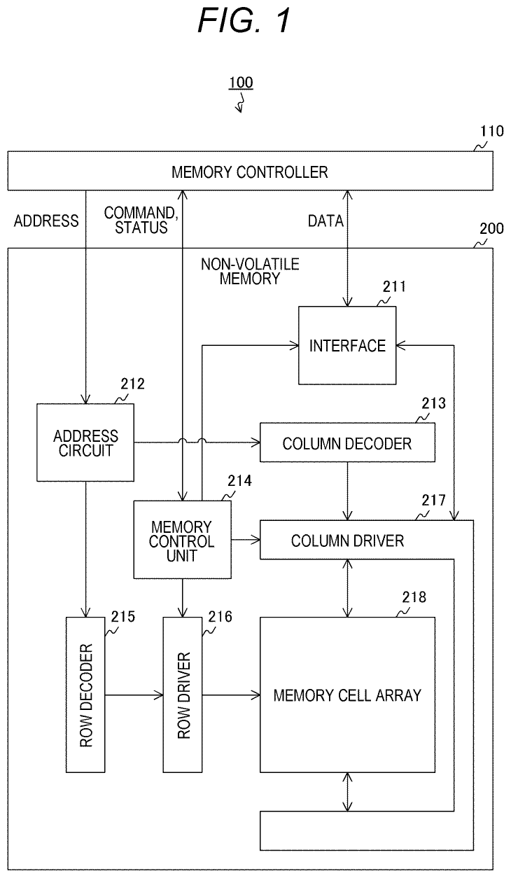

FIG. 1 is a block diagram illustrating a configuration example of a semiconductor storage device 100 of an embodiment. The semiconductor storage device 100 can be mounted on various devices and equipment such as an entertainment device, a music player, a communication device, an in-vehicle electronic device, an industrial machine, a home electronic device, an artificial satellite, a computer, and the like.

The semiconductor storage device 100 includes a memory controller 110 and a non-volatile memory 200. As the non-volatile memory 200, for example, a magnetic random access memory (MRAM) is used.

The non-volatile memory 200 includes an interface 211, an address circuit 212, a column decoder 213, a memory control unit 214, a column driver 217, a row decoder 215, a row driver 216, and a memory cell array 218.

The memory controller 110 controls the non-volatile memory 200. When a host computer (not illustrated) gives an instruction to write data, the memory controller 110 generates a write address of a write destination and a write command, and generates write data by encoding the data. Then, the memory controller 110 supplies the write address to the address circuit 212, supplies the write command to the memory control unit 214, and supplies the write data to the interface 211. In addition, the memory controller 110 receives a status indicating a command execution status and the like from the memory control unit 214.

On the other hand, when reading of data is instructed by the host computer, the memory controller 110 generates a read address of a read destination and a read command, and supplies the read address to the address circuit 212 and the read command to the memory control unit 214. Then, the memory controller 110 receives the read data from the interface 211 and decodes the read data. In addition, the memory controller 110 receives the status from the memory control unit 214.

The interface 211 transmits and receives data to and from the memory controller 110 under the control of the memory control unit 214. The interface 211 exchanges read data and write data with the column driver 217 and the memory controller 110. In addition, the interface 211 exchanges statuses with the memory control unit 214 and the memory controller 110.

The address circuit 212 separates the address received from the memory controller 110 into a row address and a column address. The row address designates a row of an access destination in the memory cell array 218. Meanwhile, the column address designates a column of an access destination in the memory cell array 218. The address circuit 212 supplies a row address to the row decoder 215 and supplies a column address to the column decoder 213.

The column decoder 213 analyzes the column address received from the address circuit 212 and selects a column corresponding to the column address.

The memory control unit 214 controls the interface 211, the column driver 217, and the row driver 216 in accordance with a command from the memory controller 110.

In a case where the command is a read command, the memory control unit 214 instructs the column driver 217 and the row driver 216 to read data. On the other hand, in a case where the command is a write command, the memory control unit 214 instructs the column driver 217 and the row driver 216 to perform writing. In addition, the memory control unit 214 generates a status and supplies the status to the memory controller 110.

The row decoder 215 analyzes the row address received from the address circuit 212 and selects a row corresponding to the row address.

The row driver 216 applies a voltage to the memory cell under the control of the memory control unit 214. When reading or writing is instructed, the row driver 216 controls the voltage of the memory cell of the row selected by the row decoder 215.

The column driver 217 applies a voltage to the memory cell under the control of the memory control unit 214. When reading is instructed by the memory control unit 214, the column driver 217 controls the voltage of the memory cell of the column selected by the column decoder 213. Then, the column driver 217 reads read data from the memory cell of the access destination and supplies the read data to the interface 211.

Furthermore, when writing is instructed by the memory control unit 214, the column driver 217 sequentially performs write processing of writing write data, sense processing of reading the written data, and verification processing of determining whether or not the writing has succeeded. Then, when the writing fails, the column driver 217 writes the write data again. Moreover, the column driver 217 performs precharge processing. Details and the execution timing of the precharge processing will be described later.

Note that a plurality of non-volatile memories 200 can be mounted in the semiconductor storage device 100. In this case, at the time of WVW control, since the write operation is spontaneously stopped in each of the non-volatile memories 200, the memory controller 110 may perform control on these memories using a common control signal.

### [Configuration Example of Memory Cell Array]

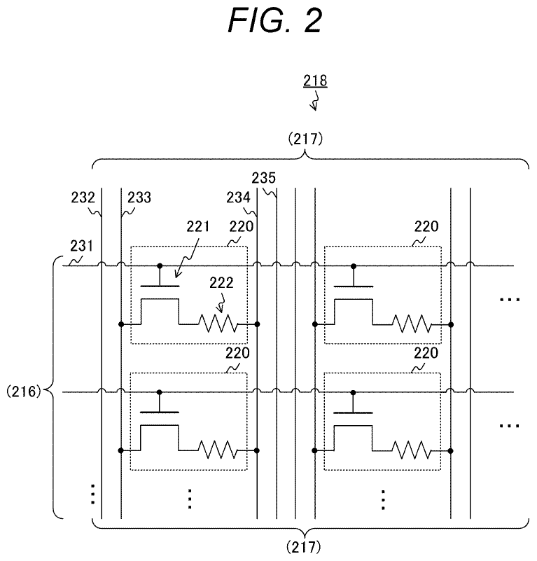

FIG. 2 is a circuit diagram illustrating a configuration example of the memory cell array 218 of a first embodiment of the present technology. In the memory cell array 218, a plurality of memory cells 220 is arranged in a matrix.

Additionally, in the memory cell array 218, a word line 231 is wired for each row, and a data line 232, a source line 233, a bit line 234, and a sense line 235 are wired for each column. Each of the memory cells 220 is inserted between the source line 233 and the bit line 234 of the corresponding column. In addition, the data line 232, the source line 233, the bit line 234, and the sense line 235 are connected to the column driver 217, and the voltages of the signal lines are controlled. Note that the source line 233 and the bit line 234 are an example of a pair of signal lines described in the claims.

In addition, the memory cell 220 includes an n-channel metal oxide semiconductor (nMOS) transistor 221 and an MTJ element 222. The nMOS transistor 221 and the MTJ element 222 are connected in series between the source line 233 and the bit line 234 of the corresponding column. Furthermore, the gate of the nMOS transistor 221 is connected to the word line 231 of the corresponding row. The word line 231 is connected to the row driver 216, and the gate voltage of the nMOS transistor 221 is controlled by this driver.

The MTJ element 222 is an element in which the internal magnetization direction changes according to the direction of the current flowing at the time of writing, and the resistivity changes. A state in which the resistivity of the MTJ element 222 is higher than a predetermined value is referred to as a high resistivity state, and a state in which the resistivity is lower than a predetermined value is referred to as a low resistance state. A logical value “1” is assigned to one of the high resistance state and the low resistance state, and a logical value “0” is assigned to the other. In addition, by supplying a current smaller than that at the time of writing at the time of reading, data can be read from the memory cell 220 in a non-destructive manner. Note that the MTJ element 222 is an example of a resistive element described in the claims.

### [Configuration Example of Column Driver]

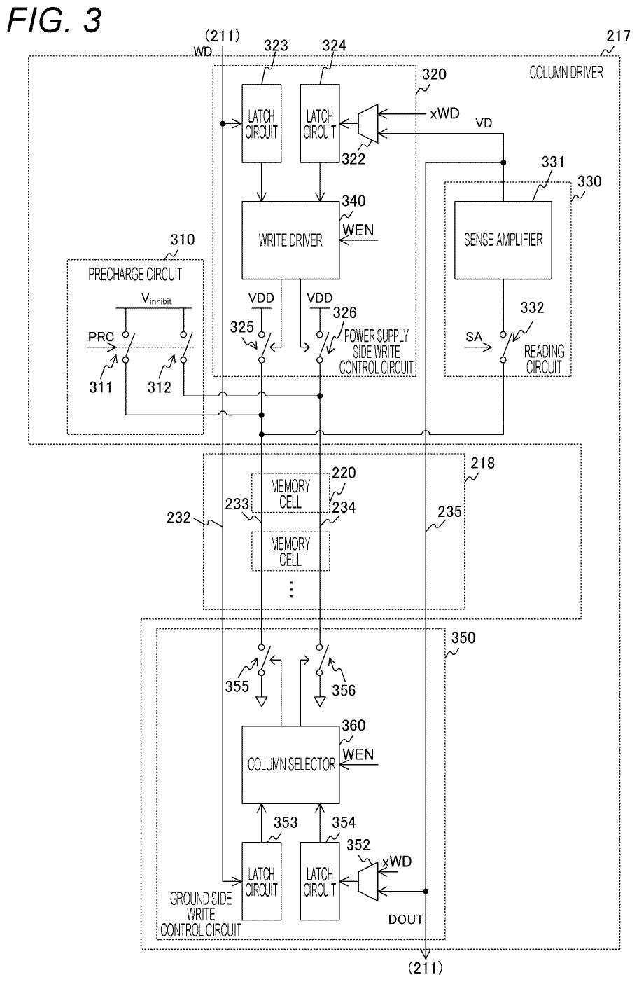

FIG. 3 is a block diagram illustrating a configuration example of the column driver 217 of the first embodiment of the present technology. The column driver 217 includes a precharge circuit 310, a power supply side write control circuit 320, a reading circuit 330, and a ground side write control circuit 350 for each column. When the total number of columns is N (N is an integer), N precharge circuits 310, N power supply side write control circuits 320, N reading circuits 330, and N ground side write control circuits 350 are disposed. The precharge circuit 310, the power supply side write control circuit 320, and the reading circuit 330 are disposed on the power supply side of the corresponding column, and the ground side write control circuit 350 is disposed on the ground side of the corresponding column.

The precharge circuit 310 performs precharge processing under the control of the memory control unit 214. The precharge circuit 310 includes precharge switches 311 and 312.

The precharge switch 311 opens and closes a path between the source line 233 of the corresponding column and the node of an inhibition voltage V_{inhibit} according to a control signal PRC from the memory control unit 214. The precharge switch 312 opens and closes a path between the bit line 234 and the node of the inhibition voltage V_{inhibit} according to the control signal PRC. The inhibition voltage V_{inhibit} is a voltage supplied to source line 233 and bit line 234 at the time of precharge, and is set to a value different from a reference voltage (ground voltage or the like). For example, an intermediate voltage between a power supply voltage VDD and the reference voltage is used as the inhibition voltage V_{inhibit}.

The power supply side write control circuit 320 supplies a predetermined power supply voltage VDD to one signal line corresponding to write data among the source line 233 and the bit line 234 at the time of writing. The power supply side write control circuit 320 includes a selector 322, latch circuits 323 and 324, a write driver 340, and switches 325 and 326.

Here, an access unit of the non-volatile memory 200 is M (M is an integer) bits. It is assumed that M write drivers 340 in the column driver 217 operate in parallel, and can read or write data with M columns as access targets.

The latch circuit 323 fetches and holds write data WD. An input terminal of the latch circuit 323 is connected to the data line 232. In addition, the latch circuit 323 supplies the held write data WD to the write driver 340. Note that the latch circuit 323 is an example of a first latch circuit described in the claims.

The selector 322 selects either inverted data xWD obtained by inverting the write data WD or verification data VD from the reading circuit 330 under the control of the memory control unit 214. The selector 322 supplies the selected data to the latch circuit 324. Note that the inverter that inverts the write data WD is omitted in the drawing.

The latch circuit 324 fetches and holds data from the selector 322. The latch circuit 324 supplies the held data to the write driver 340. Note that the latch circuit 324 is an example of a second latch circuit described in the claims.

The write driver 340 controls the switches 325 and 326 on the basis of the data held in the latch circuits 323 and 324, respectively, and supplies the power supply voltage VDD to one of the source line 233 and the bit line 234.

The switch 325 opens and closes a path between the node of the power supply voltage VDD and the source line 233 under the control of the write driver 340. The switch 326 opens and closes a path between the node of the power supply voltage VDD and the bit line 234 under the control of the write driver 340.

The reading circuit 330 reads data from the access target memory cell 220 under the control of the memory control unit 214. The reading circuit 330 includes a sense amplifier 331 and a sense switch 332.

The sense amplifier 331 reads data from the access target memory cell 220 via the sense switch 332. The sense amplifier 331 supplies the read data as the verification data VD to the power supply side write control circuit 320 and the ground side write control circuit 350. In addition, in a case where a read command is input to the memory controller 110, data read by the sense amplifier 331 is output to the interface 211 as read data DOUT.

The sense switch 332 opens and closes a path between the sense amplifier 331 and the source line 233 in accordance with a control signal SA from the memory control unit 214.

The ground side write control circuit 350 connects one signal line corresponding to write data among the source line 233 and the bit line 234 and the node of the reference voltage at the time of writing. The ground side write control circuit 350 includes a selector 352, latch circuits 353 and 354, a column selector 360, and switches 355 and 356.

The selector 352 selects either the inverted data xWD or the verification data VD from the reading circuit 330 under the control of the memory control unit 214. The selector 352 supplies the selected data to the latch circuit 354.

The latch circuit 353 fetches and holds the write data WD. An input terminal of the latch circuit 353 is connected to the data line 232. In addition, the latch circuit 353 supplies the held write data WD to the column selector 360. Note that the latch circuit 353 is an example of a third latch circuit described in the claims.

The latch circuit 354 fetches and holds data from the selector 352. The latch circuit 354 supplies the held data to the column selector 360. Note that the latch circuit 354 is an example of a fourth latch circuit described in the claims.

The column selector 360 controls the switches 355 and 356 on the basis of the data held in the latch circuits 353 and 354, respectively, and connects one of the source line 233 and the bit line 234 to the node of the reference voltage.

The switch 355 opens and closes a path between the node of the reference voltage and the source line 233 under the control of the column selector 360. The switch 356 opens and closes a path between the node of the reference voltage and the bit line 234 under the control of the column selector 360.

When a write command is input to the memory controller 110, a circuit including the power supply side write control circuit 320 and the ground side write control circuit 350 performs write processing.

Immediately before the write processing, the precharge circuit 310 performs precharge processing of supplying the inhibition voltage V_{inhibit} to both the source line 233 and the bit line 234.

In the write processing, the latch circuits 323 and 353 hold the write data WD, and the latch circuits 324 and 354 hold the inverted data xWD thereof. The power supply side write control circuit 320 controls the switches 325 and 326 to supply the power supply voltage VDD to one of the source line 233 and the bit line 234 corresponding to the write data WD. Meanwhile, the ground side write control circuit 350 controls the switches 355 and 356 to connect one of the source line 233 and the bit line 234 to which the power supply voltage VDD is not supplied and the node of the reference voltage. By these control, write data is written to the M access target memory cells 220 under the control described above.

After the write processing, the reading circuit 330 reads data from the access target memory cell 220, and causes the latch circuits 324 and 354 to hold the data as the verification data VD. This processing corresponds to the above-described sense processing.

Then, after the sense processing, the power supply side write control circuit 320 and the ground side write control circuit 350 perform verification processing of reading and comparing the write data WD and the verification data VD from the latch circuits 323 and 324 and the like. A match between these pieces of data indicates that writing has succeeded, and a mismatch indicates that writing has failed. The verification processing is performed for each column.

When writing is successful, the power supply side write control circuit 320 and the ground side write control circuit 350 turn off the switches 325, 326, 355, and 356, and bring the source line 233 and the bit line 234 into a floating state. On the other hand, when the writing fails, the power supply side write control circuit 320 and the ground side write control circuit 350 supply the power supply voltage VDD to one of the source line 233 and the bit line 234 corresponding to the write data WD, and set the other as the reference voltage. As a result, the write data WD is written again. Processing of performing one of the transition to the floating state and the rewriting depending on whether or not the writing has succeeded is hereinafter referred to as “write retry processing”. Note that the circuit including the power supply side write control circuit 320 and the ground side write control circuit 350 is an example of a write control circuit described in the claims.

In addition, the precharge circuit 310 performs the precharge processing immediately before the write retry processing in addition to immediately before the write processing. For example, precharge processing is executed between sense processing and write retry processing.

As described above, the control of sequentially performing the write processing, the verification processing, and the write retry processing is referred to as “write verify write (WVW) control”. In this WVW control, the precharge circuit 310 starts the precharge processing again between the sense processing and the write retry processing, so that a decrease in the life of the non-volatile memory 200 can be curbed. Details of the reason will be described later.

### [Configuration Example of Write Control Circuit]

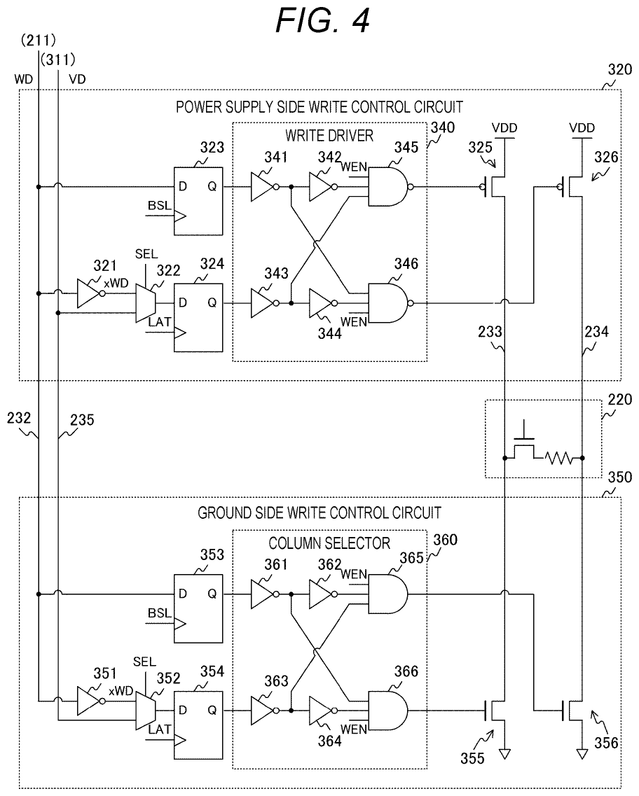

FIG. 4 is a block diagram illustrating a configuration example of the power supply side write control circuit 320 and the ground side write control circuit 350 in the first embodiment of the present technology. As the switches 325 and 326, for example, p-channel MOS (pMOS) transistors are used. In addition, as the switches 355 and 356, for example, nMOS transistors are used.

The power supply side write control circuit 320 includes an inverter 321, the selector 322, the latch circuits 323 and 324, the write driver 340, and the switches 325 and 326. The write driver 340 includes inverters 341 to 344 and negative AND (NAND) gates 345 and 346.

An input terminal D of the latch circuit 323 is connected to the data line 232, and an output terminal Q of the latch circuit 323 is connected to the inverter 341. In addition, a state (a latched state or a through state) of the latch circuit 323 is controlled by a control signal BSL from the memory control unit 214. Before the write processing, the memory control unit 214 sets the latch circuit 323 to the through state by the control signal BSL to fetch the write data WD. Immediately thereafter, the memory control unit 214 sets the latch circuit 323 to the latched state by the control signal BSL to hold the write data WD.

The inverter 321 inverts the write data WD and supplies the inverted data xWD to the selector 322.

The selector 322 selects either the inverted data xWD or the verification data VD from the sense amplifier 331 according to a control signal SEL from the memory control unit 214. The memory control unit 214 uses the control signal SEL to select the inverted data xWD at the time of the write processing and select the verification data VD after the verification processing.

The input terminal D of the latch circuit 324 is connected to the output terminal of the selector 322, and the output terminal Q is connected to the inverter 343. The state of the latch circuit 324 is controlled by a control signal LAT from the memory control unit 214. Immediately before the verification processing, the memory control unit 214 sets the latch circuit 323 to the through state by the control signal LAT to fetch the verification data VD. Immediately thereafter, the memory control unit 214 sets the latch circuit 324 to the latched state by the control signal LAT to hold the verification data VD.

In the write driver 340, the inverter 341 inverts the write data WD from the latch circuit 323 and supplies the inverted write data WD to the inverter 342 and the NAND gate 346. The inverter 342 inverts data from the inverter 341 and supplies the inverted data to the NAND gate 345.

The inverter 343 inverts data from the latch circuit 324 and supplies the inverted data to the inverter 344 and the NAND gate 345. The inverter 344 inverts data from the inverter 343 and supplies the inverted data to the NAND gate 346.

The NAND gate 345 outputs a negative AND of the data from each of the inverters 342 and 343 and a write enable signal WEN from the memory control unit 214. An output terminal of the NAND gate 345 is connected to the gate of a pMOS transistor that functions as the switch 325. The write enable signal WEN is set to a high level when the write function is enabled, and is set to a low level when the write function is disabled.

The NAND gate 346 outputs a negative AND of data from each of the inverters 341 and 344 and the write enable signal WEN. An output terminal of the NAND gate 346 is connected to the gate of a pMOS transistor that functions as the switch 326.

The memory control unit 214 sets the write enable signal WEN to the high level (enable) during the write processing and the write retry processing, and sets the write enable signal WEN to the low level (disable) within other periods.

The ground side write control circuit 350 includes an inverter 351, the selector 352, the latch circuits 353 and 354, the column selector 360, and the switches 355 and 356. The column selector 360 includes inverters 361 to 364 and AND gates 365 and 366. The connection configuration of these elements is similar to that of the power supply side write control circuit 320. Note, however, that the output terminal of the AND gate 365 is connected to the gate of an nMOS transistor that functions as the switch 356. In addition, an output terminal of the AND gate 366 is connected to the gate of an nMOS transistor that functions as the switch 355.

Note that the circuit configurations of the power supply side write control circuit 320 and the ground side write control circuit 350 are not limited to those illustrated in FIG. 3 as long as the functions described in FIG. 3 can be implemented.

### [Operation Example of Non-Volatile Memory]

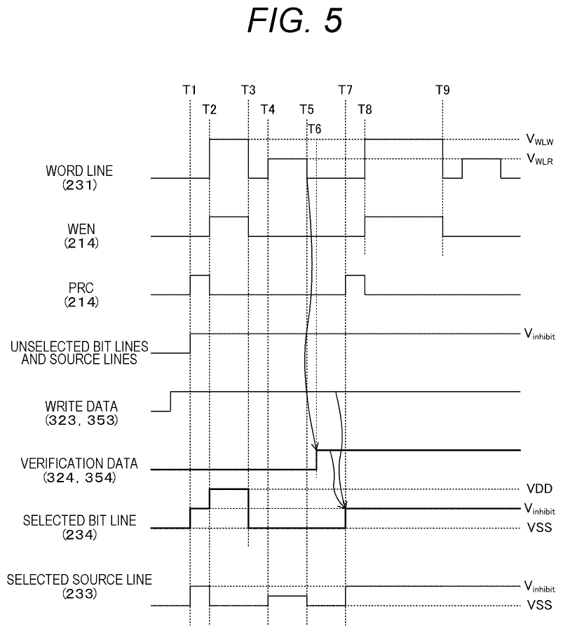

FIG. 5 is a timing chart illustrating a configuration example of an operation of the non-volatile memory 200 of a column in which writing has succeeded in the first embodiment of the present technology. It is assumed that high-level data is supplied as write data and held in the latch circuits 323 and 353.

The memory control unit 214 sets the control signal PRC to the high level over a precharge period from timings T1 to T2 immediately before write processing. As a result, the levels of the bit lines 234 and the source lines 233 of all the columns are precharged to the inhibition voltage V_{inhibit}. The value of the inhibition voltage V_{inhibit} is set to, for example, an intermediate voltage between the power supply voltage VDD and the reference voltage (such as a ground voltage VSS).

Here, the bit line 234 and the source line 233 are wired for each column, and the bit line 234 and the source line 233 of the column selected as the access target are referred to as a “selected bit line” and a “selected source line”, respectively. On the other hand, the bit lines 234 and the source lines 233 of the columns that are not selected as the access target are referred to as “unselected bit lines” and “unselected source lines”, respectively.

The row driver 216 supplies a pulse of a write voltage V_{WLW} to the word line 231 over a write period from timings T2 to T3. Furthermore, within this period, the memory control unit 214 sets the write enable signal WEN to the high level (enable). By these control, one of the selected bit line and the selected source line is set to the power supply voltage VDD, and the other is set to the ground voltage VSS. For example, when the write data is at the high level, the selected bit line is set to the power supply voltage VDD, and the selected source line is set to the ground voltage VSS.

Note that when the write data is at the low level, the selected bit line is set to the ground voltage VSS, and the selected source line is set to the power supply voltage VDD.

Then, the row driver 216 supplies a pulse of a read voltage V_{WLR} to the word line 231 over a read period from timings T4 to T5 after the write period. The read voltage V_{WLR} is set to a value lower than the write voltage V_{WLW}. As a result, a current smaller than that at the time of writing flows through the memory cell, and data is read nondestructively.

At timing T6 immediately after the read period, the latch circuits 324 and 354 fetch and hold the read verification data.

In the verification period from timings T6 to T7, the write control circuits (the power supply side write control circuit 320 and the ground side write control circuit 350) read and compare the write data and the verification data from the latch circuit 323 and the like. In FIG. 5, it is assumed that the verification data is the same (high level) as the write data and that the writing has succeeded.

The memory control unit 214 sets the control signal PRC to the high level over a precharge period from timings T7 to T8. As a result, the levels of the bit lines 234 and the source lines 233 of all the columns are precharged to the inhibition voltage V_{inhibit}.

Then, in a write retry period from timings T8 to T9, the row driver 216 supplies a pulse of the write voltage V_{WLW} to the word line 231. Furthermore, within this period, the memory control unit 214 sets the write enable signal WEN to the high level (enable). The pulse width at the time of write retry is assumed to be longer than the pulse width at the time of writing. Within this period, the write control circuit of the column in which writing has succeeded brings the selected bit line and the selected word line into a floating state.

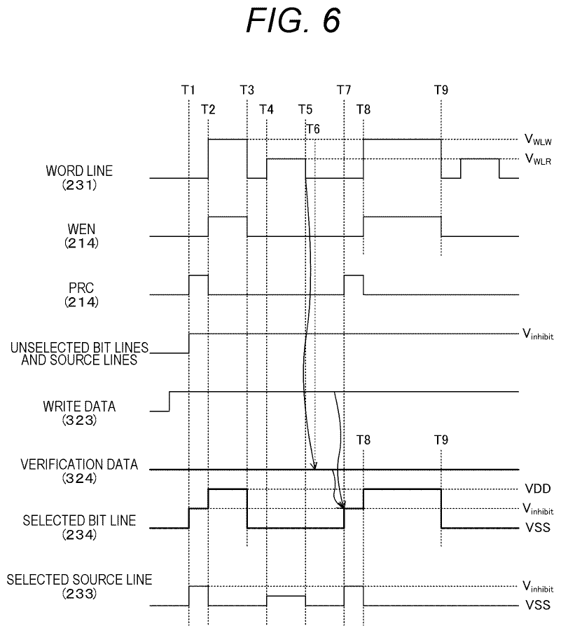

FIG. 6 is a timing chart illustrating a configuration example of an operation of the non-volatile memory 200 of a column in which writing has failed in the first embodiment of the present technology. Description will be given focusing on differences from the case where writing has succeeded.

At timing T6 immediately after the read period, the latch circuits 324 and 354 fetch and hold the read verification data, but the verification data of a certain column is assumed to have a value (low level) different from that of the write data. That is, it is assumed that writing has failed.

The bit line and the source line are precharged within a precharge period from timings T7 to T8. Then, in the write retry period from timings T8 to T9, the write control circuit of the column in which writing has failed sets the selected bit line to the power supply voltage VDD and the selected source line to the ground voltage VSS.

Here, a configuration in which precharge processing is not started between the sense processing and the write retry processing is assumed as a comparative example. In the comparative example, the level of each of the source line and the bit line of the column in which writing has succeeded at the time of the write retry processing is set to the ground voltage VSS. Additionally, in the write retry processing, the write voltage V_{WLW} is applied to the column in which writing has failed via the word line 231. Since the column in which writing has succeeded shares the word line 231 with the column in which writing has failed, the write voltage V_{WLW} is also applied to the gate of the nMOS transistor 221 of the column in which writing has failed. Accordingly, if the ground voltage VSS is set to 0 volt, the write voltage V_{WLW} is applied between the gate and the source of the nMOS transistor 221 of the column in which writing has succeeded. Since the pulse width at the time of write rewrite is longer than that at the time of writing, the voltage stress of the nMOS transistor 221 increases as the pulse width increases.

On the other hand, in a case where the precharge processing is started between the write processing and the write retry processing, as illustrated in FIG. 5, the bit line and the source line of the column in which writing has succeeded are set to the inhibition voltage V_{inhibit} by the precharge processing. Therefore, at the time of write retry, V_{WLW}−V_{inhibit} is applied between the gate and the source of the nMOS transistor 221 in which writing has succeeded, and the voltage stress is reduced as compared with the comparative example. The voltage stress between the gate and the drain is also reduced. As a result, the life of the non-volatile memory can be extended as compared with the comparative example.

Note that the pulse width of the write voltage V_{WLW} in the write retry processing is longer than that in the write processing, but may be the same as that in the write processing. In this case, it is desirable to make the write voltage in the write retry processing higher than that in the write processing.

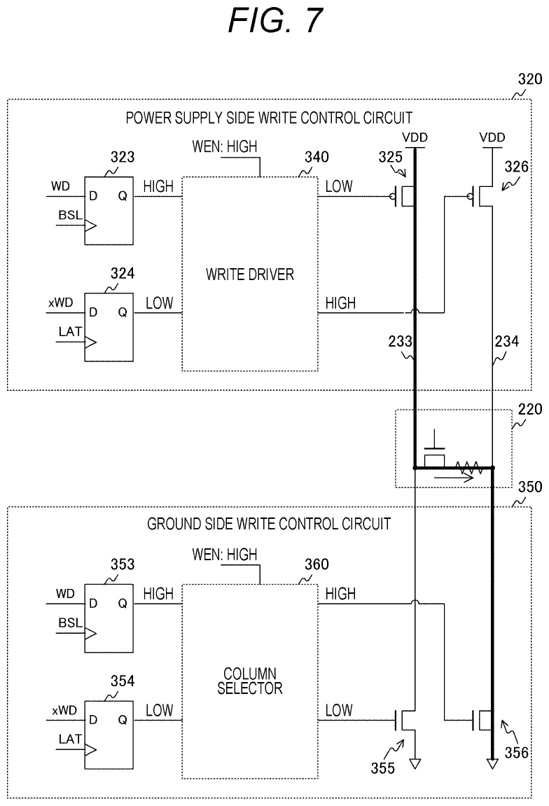

FIG. 7 is a diagram for describing voltages of the source line 233 and the bit line 234 during the write processing in the first embodiment of the present technology. It is assumed that the high-level write data WD is held in the latch circuits 323 and 353, and the low-level inverted data xWD is held in the latch circuits 324 and 354.

When the write enable signal WEN is set to the high level (enable), the write driver 340 turns on the switch 325 on the source line side and turns off the switch 326 on the bit line side. In addition, the column selector 360 turns off the switch 355 on the source line side and turns on the switch 356 on the bit line side. As a result, a current flows from the source line 233 to the bit line 234, and the high-level write data WD is written to the memory cell 220. Note that in a case where the write data WD is at the low level, the direction in which the current flows is reversed.

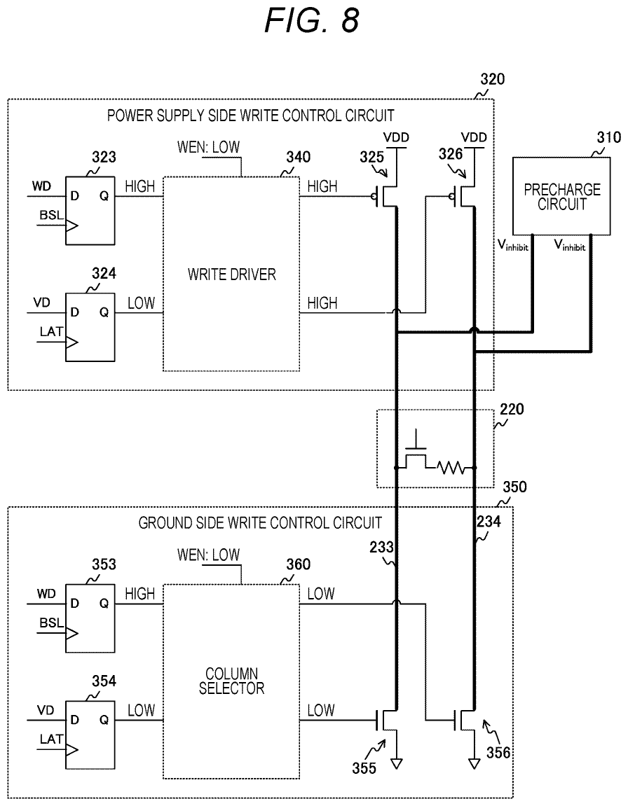

FIG. 8 is a diagram for describing voltages of the source line 233 and the bit line 234 during the precharge processing in the first embodiment of the present technology. The write enable signal WEN is set to the low level (disable), and the write driver 340 turns off the switches 325 and 326 regardless of the value of the latch circuit. Moreover, the column selector 360 also turns off the switches 355 and 356.

The precharge circuit 310 supplies the inhibition voltage V_{inhibit} to the source line 233 and the bit line 234.

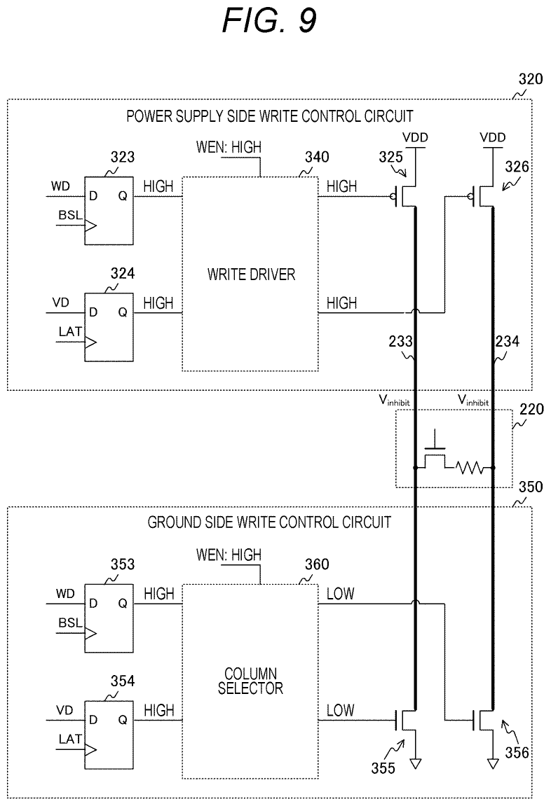

FIG. 9 is a diagram for describing the voltages of the source line 233 and the bit line 234 at the time of write retry processing of a column in which writing has succeeded in the first embodiment of the present technology. In the column illustrated in FIG. 9, it is assumed that both the write data WD and the verification data VD are at the high level and writing has succeeded.

When the write enable signal WEN is set to the high level (enable), the write driver 340 turns off the switches 325 and 326, and the column selector 360 turns off the switches 355 and 356. As a result, the source line 233 and the bit line 234 are brought into a floating state. These voltages are set to the inhibition voltage V_{inhibit} by the immediately preceding precharge processing. Therefore, the gate-source voltage and the gate-drain voltage of the nMOS transistor 221 are smaller than those in the comparative example, and the voltage stress is reduced.

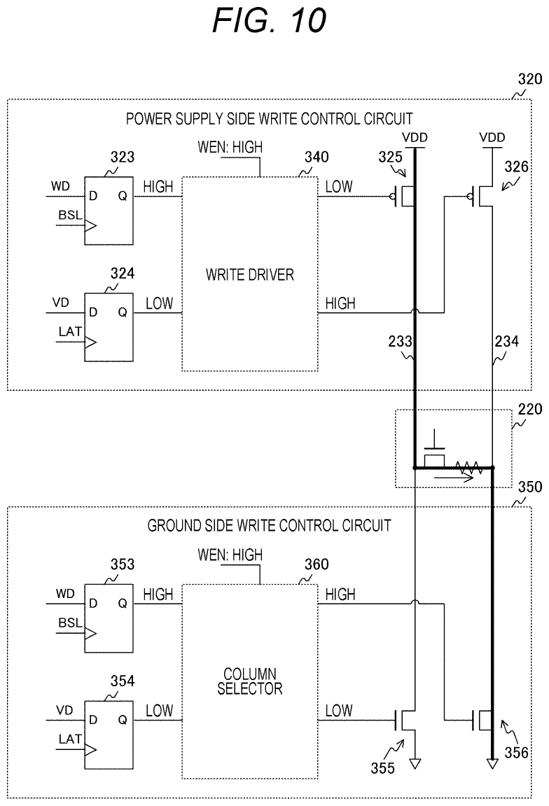

FIG. 10 is a diagram for describing the voltages of the source line 233 and the bit line 234 at the time of write retry processing of a column in which writing has failed in the first embodiment of the present technology. In the column illustrated in the FIG. 10, it is assumed that the write data WD is at the high level, whereas the verification data VD is at the low level, and writing has failed.

When the write enable signal WEN is set to the high level (enable), the write driver 340 turns on the switch 325 and turns off the switch 326. In addition, the column selector 360 turns off the switch 355 and turns on the switch 356. As a result, a current flows from the source line 233 to the bit line 234, and the write data WD is written again to the memory cell 220.

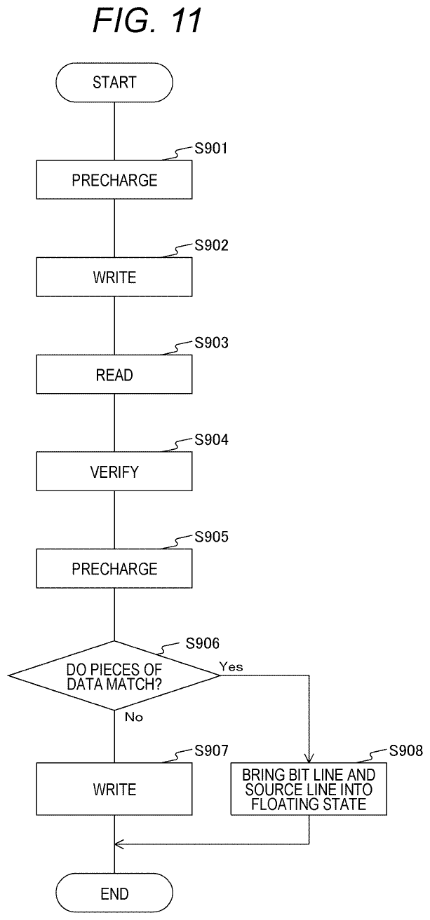

FIG. 11 is a flowchart illustrating an example of an operation of the non-volatile memory 200 of the first embodiment of the present technology. This operation is started when a write command is input to the non-volatile memory 200. In addition, the control illustrated in FIG. 11 is executed in parallel for each column. FIG. 11 is described focusing on any one of the M access target columns.

The precharge circuit 310 in the column performs precharge (step S901). Then, the column driver 217 writes write data (step S902), and reads the written data as verification data (step S903). The column driver 217 performs verification of comparing the write data and the verification data for each column (step S904). In addition, the precharge circuit 310 performs precharge (step S905).

The power supply side write control circuit 320 determines whether or not the write data and the verification data match (step S906). If it is determined that these pieces of data do not match (step S906: No), the write control circuit such as the write control circuit 320 writes the write data again (step S907).

On the other hand, if it is determined that the write data and the verification data match (step S906: Yes), the write control circuit brings the bit line and the source line into a floating state (step S908). After step S907 or S908, the non-volatile memory 200 ends the operation for writing.

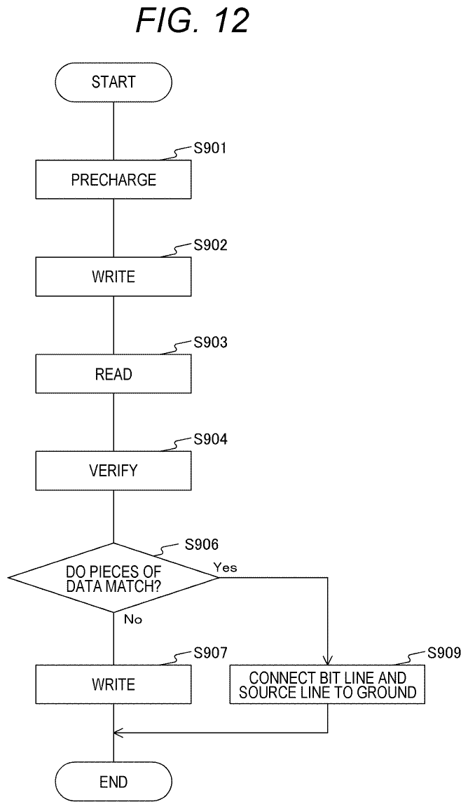

FIG. 12 is a flowchart illustrating an example of an operation of the non-volatile memory 200 of the comparative example. In this comparative example, the control up to verification in step S904 is similar to the control illustrated in FIG. 11.

In the comparative example, after step S904, no precharge is performed, and step S906 is executed. Then, if it is determined that the write data and the verification data do not match (step S906: No), the write control circuit writes the write data again (step S907).

On the other hand, if it is determined that the write data and the verification data match (step S906: Yes), the write control circuit of the column sets the bit line and the source line to the ground voltage (step S909).

As illustrated in FIG. 12, in the comparative example in which the precharge is not performed immediately before the write retry, the bit line and the source line of the column in which the writing has succeeded are set to the ground voltage. On the other hand, as illustrated in FIG. 11, in the control in which the precharge is performed immediately before the write retry, the bit line and the source line of the column in which the writing has succeeded are set to the inhibition voltage V_{inhibit}. As a result, the gate-source voltage and the gate-drain voltage of the nMOS transistor 221 of the column in which writing has succeeded become smaller than those in the comparative example, and the voltage stress is reduced.

As described above, according to the first embodiment of the present technology, since the precharge circuit 310 performs the precharge processing between the sense processing and the write retry processing, it is possible to reduce the voltage stress of the column in which writing has succeeded. As a result, a decrease in the life of the non-volatile memory 200 can be curbed.

### [Modification]

In the first embodiment described above, regardless of the verification result, the precharge circuit 310 starts the precharge processing immediately before the write retry processing, and stops the supply of the inhibition voltage V_{inhibit} during the write retry processing. However, with this configuration, in the column in which writing has succeeded, the voltages of the source line 233 and the bit line 234 in the floating state may decrease during the write retry processing. A non-volatile memory 200 in a modification of the first embodiment is different from that of the first embodiment in that the supply of an inhibition voltage V_{inhibit} is continued even during the write retry processing in the column in which writing has succeeded.

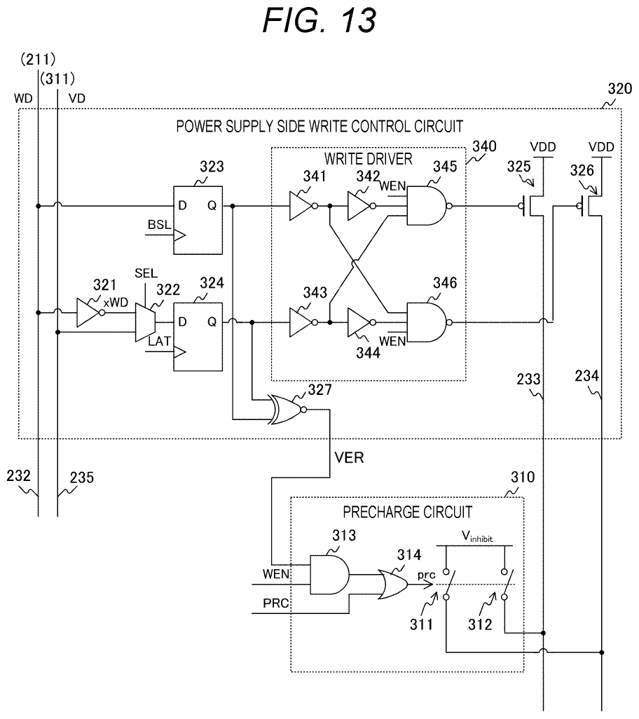

FIG. 13 is a block diagram illustrating a configuration example of a power supply side write control circuit 320 and a precharge circuit 310 of a modification of the first embodiment of the present technology. The power supply side write control circuit 320 of the modification of the first embodiment is different from that of the first embodiment in further including an exclusive negative OR (XNOR) gate 327. Furthermore, the precharge circuit 310 of the modification of the first embodiment is different from that of the first embodiment in further including a logical product (AND) gate 313 and a logical sum (OR) gate 314.

The XNOR gate 327 supplies a detection signal VER of exclusive negative OR of the held values of the latch circuits 323 and 324 to the precharge circuit 310. The detection signal VER indicates whether or not writing has succeeded (that is, the verification result).

The AND gate 313 outputs a logical product of the detection signal VER from the XNOR gate 327 and the write enable signal WEN to the OR gate 314. The OR gate 314 outputs a logical sum of a control signal PRC and the signal from the AND gate 313 to precharge switches 311 and 312 as a control signal prc.

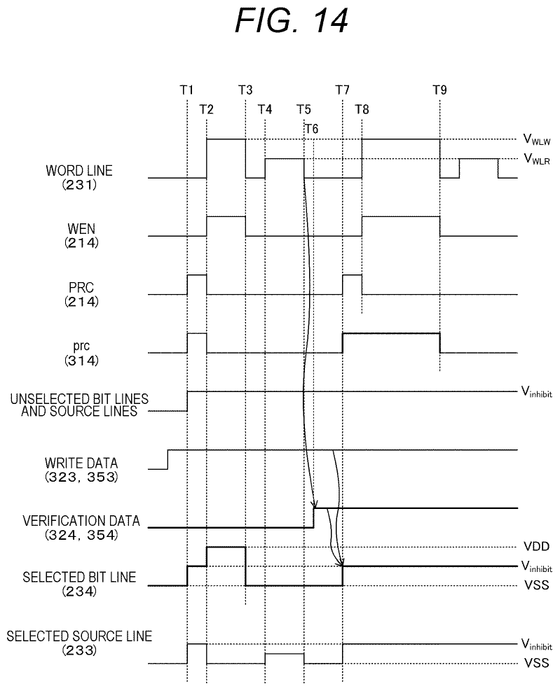

FIG. 14 is a diagram for describing precharge processing for a column in which writing has succeeded in the modification of the first embodiment of the present technology.

A memory control unit 214 sets the control signal PRC to the high level within a period from timings T1 to T2 immediately before write processing. The control signal prc is also set to the high level, and the bit lines 234 and the source lines 233 of all the columns are precharged to an inhibition voltage V_{inhibit}.

The memory control unit 214 sets the control signal PRC to the low level within a write period from timings T2 to T3. In addition, during this period, since the write data and the inverted data held by the latch circuits 323 and 324 do not match, the output of the XNOR gate 327 is set to the low level, and the output of the AND gate 313 is also set to the low level. As a result, the control signal prc is set to the low level and precharge is not performed.

In addition, the memory control unit 214 sets the control signal PRC to the high level within a period from timings T7 to T8 immediately before the write retry processing. The control signal prc is also set to the high level, and the bit lines 234 and the source lines 233 of all the columns are precharged to an inhibition voltage V_{inhibit}.

The memory control unit 214 sets the control signal PRC to the low level within a write retry period from timings T8 to T9. In the column in which writing has succeeded, the detection signal VER from the XNOR gate 327 is set to the high level, and the output of the AND gate 313 is also set to the high level. As a result, the control signal prc is set to the high level, and the precharge is continued even during the write retry processing.

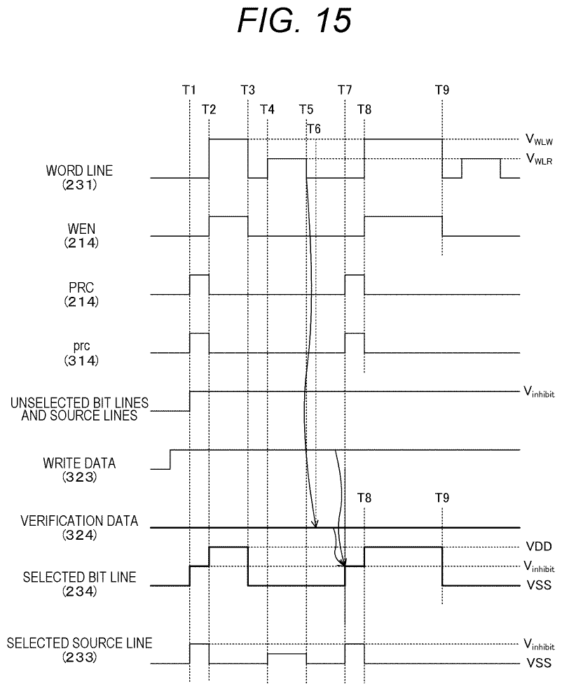

FIG. 15 is a diagram for describing precharge processing for a column in which writing has failed in a modification of the first embodiment of the present technology. Description will be given focusing on differences from the case where writing has succeeded.

As illustrated in FIG. 15, in the column in which writing has failed, the detection signal VER from the XNOR gate 327 is set to the low level and the output of the AND gate 313 is also set to the low level in the write retry period from timings T8 to T9. As a result, the control signal prc is set to the low level, and the precharge is stopped.

As illustrated in FIGS. 14 and 15, in the column in which writing has succeeded, the precharge circuit 310 continuously performs the precharge even during the write retry processing. As a result, voltage drop of the source line 233 and the bit line 234 in the floating state can be prevented.

Note that the circuit configurations of the power supply side write control circuit 320 and the precharge circuit 310 are not limited to those illustrated in FIG. 13 as long as the control illustrated in FIGS. 14 and 15 can be performed.

As described above, according to the modification of the first embodiment of the present technology, the precharge circuit 310 continuously performs the precharge even during the write retry processing for the column in which writing has succeeded. As a result, voltage drop of the source line 233 and the bit line 234 in the floating state can be prevented.

### 2. Second Embodiment

In the first embodiment described above, for each column, the reading circuit 330 supplies the verification data to the write control circuit of the column via the sense line 235, but in this configuration, it is necessary to wire the sense line 235 for each column. A non-volatile memory 200 of a second embodiment is different from that of the first embodiment in that the number of wires is reduced by supplying verification data for each sharing unit in which a reading circuit 330 shares the sense line.

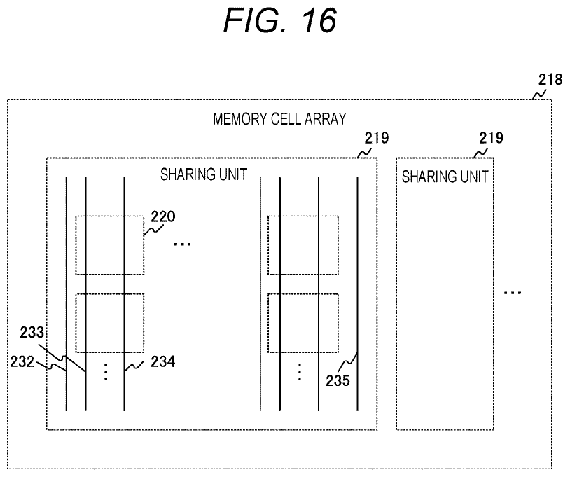

FIG. 16 is a diagram illustrating a wiring example of a memory cell array 218 of the second embodiment of the present technology. The memory cell array 218 of the second embodiment is divided into S (S is an integer) sharing units 219. Each of the sharing units 219 includes a plurality of columns, and a data line 232, a source line 233, and a bit line 234 are wired for each column. Furthermore, one sense line 235 is wired to each of the sharing units 219, and all the columns in the sharing unit 219 share the sense line 235. The access unit and the sharing unit 219 may be different.

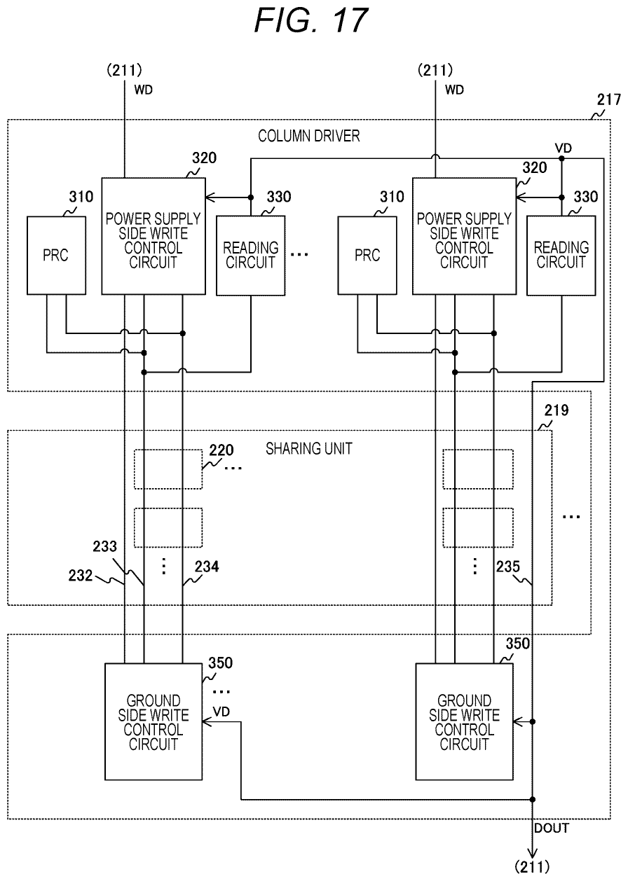

FIG. 17 is a block diagram illustrating a configuration example of a column driver 217 of the second embodiment of the present technology. A reading circuit 330 of the column driver 217 of the second embodiment outputs verification data VD to write control circuits (a power supply side write control circuit 320 and a ground side write control circuit 350) of all columns in the sharing unit 219 via the sense line 235 for each sharing unit 219.

Furthermore, in the memory cell array 218, only one sense line 235 is wired for each sharing unit 219. The sense line 235 is shared by all the columns in the sharing unit 219. Such a connection is referred to as a “burst connection”. The sense line 235 can also be used for outputting read data DOUT.

For example, when M, which is the number of access target columns, is 256 and the sharing unit 219 is 8 columns, the reading circuits 330 of the 8 columns in the sharing unit 219 sequentially output the verification data VD one by one. In this case, 32 sense lines 235 are wired for each access unit.

Note that the modification of the first embodiment can be applied to the second embodiment.

As described above, according to the second embodiment of the present technology, since the reading circuit 330 supplies the verification data VD via the sense line 235 for each sharing unit 219, the number of wirings of the memory cell array 218 can be reduced by burst connection.

### 3. Third Embodiment

In the first embodiment described above, the verification processing is performed only once, but writing may fail in the second write processing. A non-volatile memory 200 of a third embodiment is different from that of the first embodiment in that write retry processing is repeated until the number of times of verification processing reaches an upper limit value.

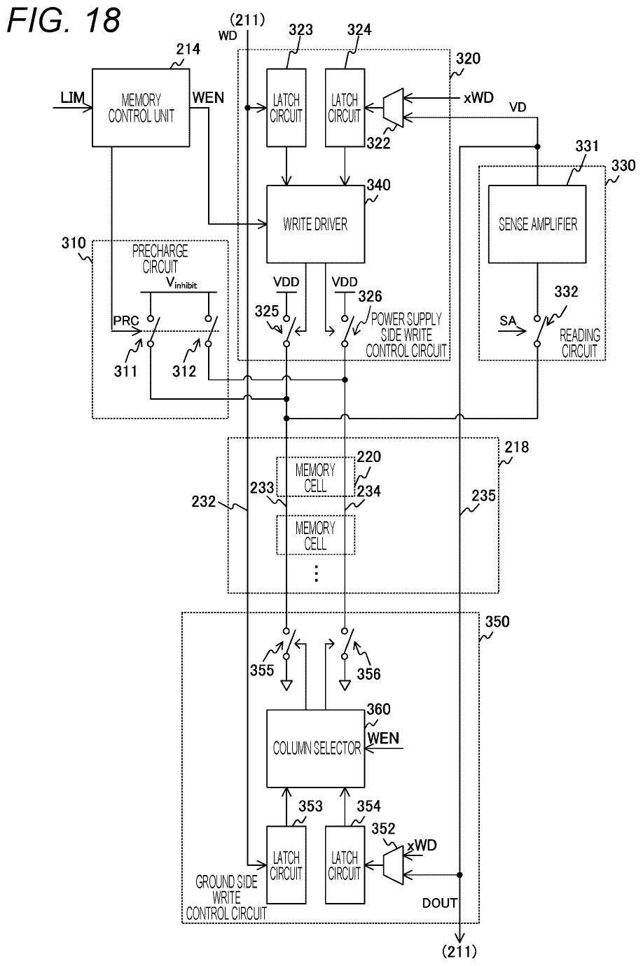

FIG. 18 is a block diagram illustrating a configuration example of a memory control unit 214 and a column driver 217 of the third embodiment of the present technology.

In addition, the memory control unit 214 in FIG. 18 counts the number of times that a write enable signal WEN has risen (that is, the number of executions of verification processing), and determines whether or not the count value has reached a predetermined upper limit value LIM. In a case where the upper limit value LIM has not been reached, the memory control unit 214 generates pulses of a control signal PRC and the write enable signal WEN, and causes precharge processing and write retry processing to be executed.

On the other hand, in a case where the number of executions of the verification processing has reached the upper limit value LIM, the memory control unit 214 notifies a memory controller 110 of a write error and ends the control for writing data.

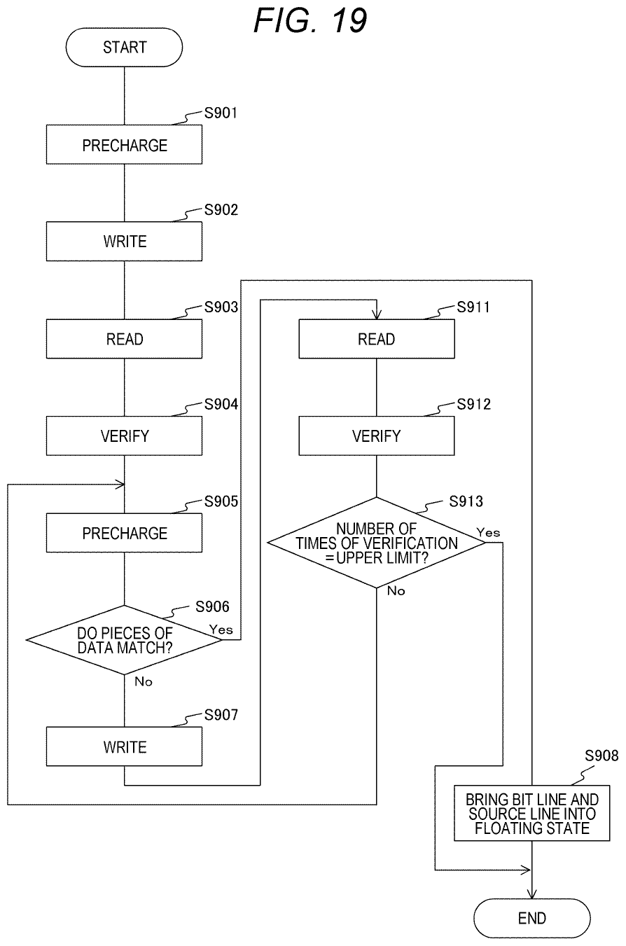

FIG. 19 is a flowchart illustrating an example of an operation of the non-volatile memory 200 of the third embodiment of the present technology. The operation of the non-volatile memory 200 of the third embodiment is different from that of the first embodiment in that steps S911 to S913 are further executed.

In the second embodiment, the operations up to step S907 are similar to those in the first embodiment. After step S907, the column driver 217 reads the written data as verification data (step S911). The column driver 217 performs verification of comparing the write data and the verification data for each column (step S912).

The memory control unit 214 determines whether or not the number of times of verification has reached the upper limit (step S913). If the number of times of verification has not reached the upper limit (step S913: No), the non-volatile memory 200 repeats step S905 and the subsequent steps.

On the other hand, if the number of times of verification has reached the upper limit (step S913: Yes), the memory control unit 214 notifies the memory controller 110 of a write error and ends the operation for writing.

As illustrated in FIG. 19, in the second or subsequent verification processing, in a case where the verification data and the write data do not match and the number of executions of the verification processing has not reached the upper limit, the write control circuit performs the write retry processing again. As a result, the reliability of writing can be further improved.

Moreover, in FIG. 19, in a case where the verification data and the write data match in the second or subsequent verification processing, the processing in the sense processing and subsequent steps is stopped. At the time of the sense processing, the voltage of each of the source line 233 and the bit line 234 is 0 volt (V) and about 0.1 volt or 0.2 volt. Although these voltages are different from the inhibition voltage V_{inhibit}, the voltages of the source line 233 and the bit line 234 are kept at the inhibition voltage V_{inhibit} by the precharge immediately before the sense processing is stopped. Therefore, the precharge processing after the sense processing is stopped becomes unnecessary. Therefore, power consumption can be further reduced.

Note that the modification of the first embodiment and the second embodiment can be applied to the third embodiment.

As described above, according to the third embodiment of the present technology, in a case where there is a mismatch in the second and subsequent verification processing and the number of executions of the verification processing is less than the upper limit, the write control circuit performs the write retry processing again, so that the reliability of writing can be further improved.

### 4. Fourth Embodiment

In the first embodiment described above, the latch circuit 354 for holding the verification data or the inverted data is disposed for each column, but with this configuration, it is difficult to reduce the number of latch circuits. A non-volatile memory 200 of a fourth embodiment is different from that of the first embodiment in that the number of latch circuits 354 in each column is reduced.

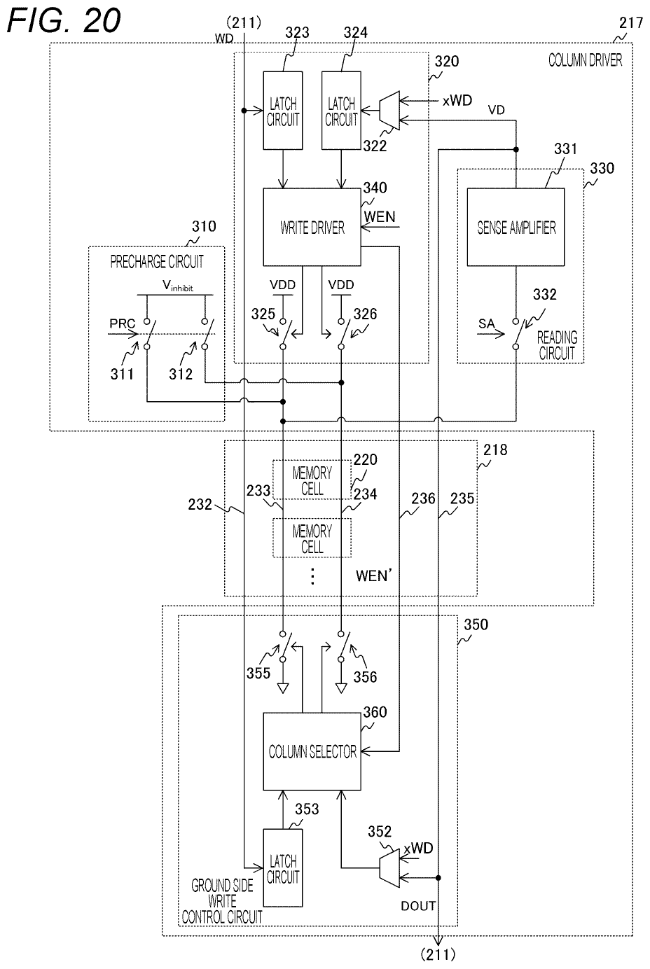

FIG. 20 is a block diagram illustrating a configuration example of a column driver 217 of the fourth embodiment of the present technology. The column driver 217 of the fourth embodiment is different from that of the first embodiment in that a latch circuit 354 is not disposed in a ground side write control circuit 350.

Furthermore, in a memory cell array 218, an enable signal line 236 is further wired for each column. A write driver 340 further generates a write enable signal WEN′ and supplies the write enable signal WEN′ to a corresponding column selector 360 via the enable signal line 236.

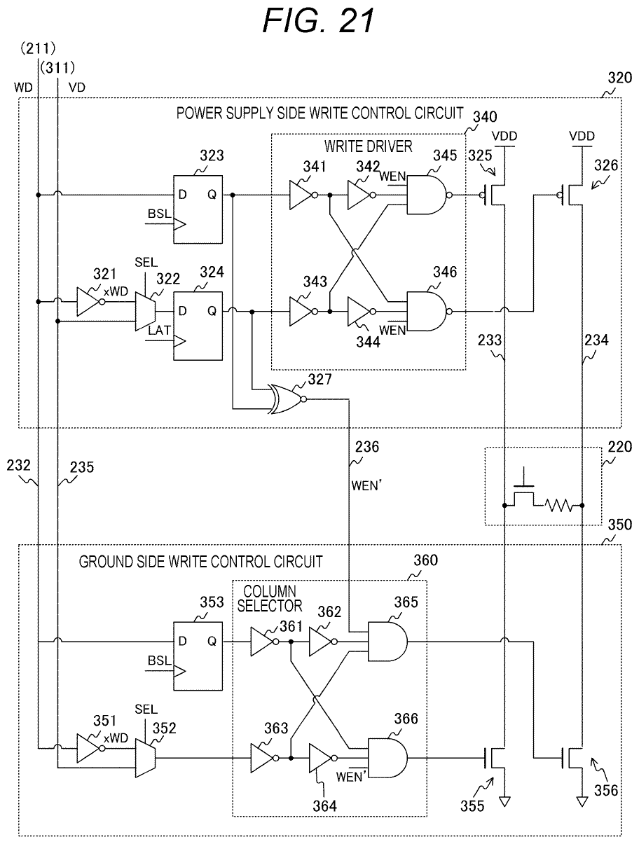

FIG. 21 is a block diagram illustrating a configuration example of a power supply side write control circuit 320 and a ground side write control circuit 350 of the fourth embodiment of the present technology. The power supply side write control circuit 320 of a modification of the fourth embodiment is different from that of the first embodiment in further including an XOR gate 328.

The XOR gate 328 supplies an exclusive OR of the held values of latch circuits 323 and 324 to a column selector 360 as the write enable signal WEN′. The write enable signal WEN′ is set to the low level (disable) in a case where writing is successful.

In addition, in the ground side write control circuit 350 of the fourth embodiment, an output signal of a selector 352 is input to an inverter 363. Furthermore, the write enable signal WEN′ is input to each of AND gates 365 and 366.

As illustrated in FIGS. 20 and 21, the write driver 340 generates the write enable signal WEN′ on the basis of the verification data and the write data and passes the write enable signal WEN′ to the ground side, so that the latch circuit 354 on the ground side can be omitted. Note, however, that in the memory cell array 218, it is necessary to further wire the enable signal line 236 in the vertical direction for each column, and when the number of wires increases, the circuit scale may increase. Therefore, the first embodiment is used in a case where priority is given to reduction of the circuit scale.

Note that the modification of the first embodiment and the second and third embodiments can be applied to the fourth embodiment.

As described above, according to the fourth embodiment of the present technology, since the write driver 340 generates the write enable signal WEN′ on the basis of the verification data and the write data and supplies the write enable signal WEN′ to the ground side, the number of latch circuits can be reduced.

### 5. Examples of Application to Mobile Body

The technology according to the present disclosure (the present technology) can be applied to various products. For example, the technology of the present disclosure may be implemented as a device mounted on any type of mobile body such as an automobile, an electric vehicle, a hybrid electric vehicle, a motorcycle, a bicycle, a personal mobility, an airplane, a drone, a ship, a robot, and the like.

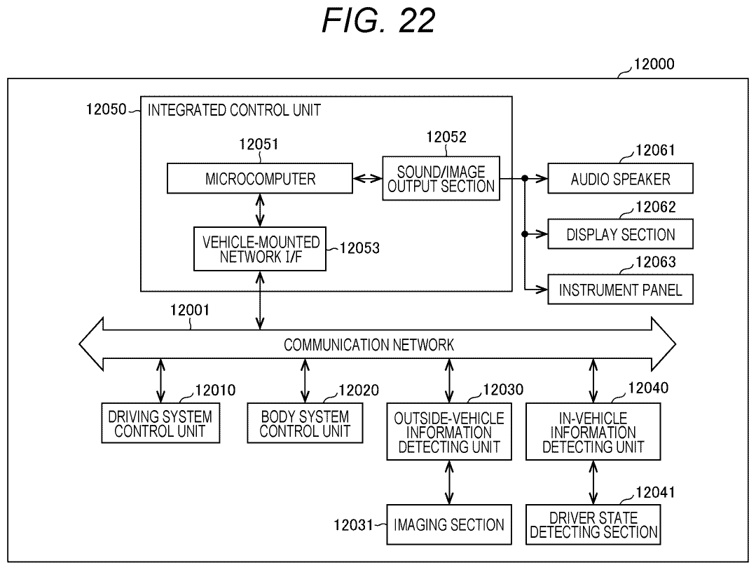

FIG. 22 is a block diagram illustrating an example of schematic configuration of a vehicle control system as an example of a mobile body control system to which the technology according to the present disclosure can be applied.

The vehicle control system 12000 includes a plurality of electronic control units connected to each other via a communication network 12001. In the example depicted in FIG. 22, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 22, an audio speaker 12061, a display section 12062, and an instrument panel 12063 are illustrated as output devices. The display section 12062 may, for example, include at least one of an on-board display and a head-up display.

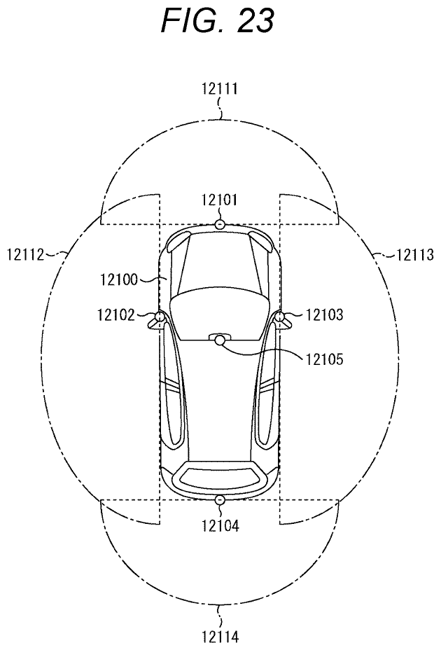

FIG. 23 is a diagram illustrating an example of the installation position of the imaging section 12031.

In FIG. 23, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within an interior of the vehicle, and the like. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 23 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology of the present disclosure can be applied has been described above. The technology according to the present disclosure can be applied to, for example, the imaging section 12031 among the configurations described above. Specifically, by applying the technology according to the present disclosure to the imaging section 12031 that can be applied to a storage device in the imaging section 12031, the semiconductor storage device 100 in FIG. 1 can curb a decrease in the life of the storage device and improve the reliability of the system.

Note that the embodiments described above show examples for embodying the present technology, and the matters in the embodiments and the matters specifying the invention in the claims have correspondence relationships. Similarly, the matters specifying the invention in the claims and matters with the same names in the embodiments of the present technology have correspondence relationships. Note, however, that the present technology is not limited to the embodiments, and can be embodied by applying various modifications to the embodiments without departing from the gist of the embodiments.

Note that the effects herein described are merely examples and are not limited, and furthermore, other effects may be obtained.

Note that the present technology may also have the following configurations.
(1) A non-volatile memory including:
a memory cell inserted between a pair of signal lines;
a write control circuit that performs write processing of supplying a predetermined power supply voltage to one signal line corresponding to write data among the pair of signal lines, and write retry processing of bringing the pair of signal lines into a floating state in a case where verification data and the write data match and supplying the power supply voltage to the signal line in a case where the verification data and the write data do not match;
a reading circuit that performs sense processing of reading data from the memory cell after the write processing and supplying the data as the verification data to the write control circuit; and
a precharge circuit that starts precharge processing of supplying an inhibition voltage different from a predetermined reference voltage to the pair of signal lines between the sense processing and the write retry processing.
(2) The non-volatile memory according to (1), in which:
the write control circuit includes a power supply side write control circuit and a ground side write control circuit;
the power supply side write control circuit includes
a first latch circuit that holds the write data,
a second latch circuit that holds either the verification data or inverted data obtained by inverting the write data, and
a write driver that causes the power supply voltage to be supplied to one of the pair of signal lines on the basis of data held in each of the first and second latch circuits; and
the ground side write control circuit includes a column selector that connects the other of the pair of signal lines and the reference voltage.
(3) The non-volatile memory according to (2), in which
the ground side write control circuit includes:
a third latch circuit that holds the write data;
a fourth latch circuit that holds either the verification data or the inverted data; and
a column selector that connects the other and the reference voltage on the basis of data held in each of the third and fourth latch circuits.
(4) The non-volatile memory according to (2), in which
the write driver generates a predetermined write enable signal on the basis of the data, and
the ground side write control circuit includes
a third latch circuit that holds the write data, and
a column selector that connects the other and the reference voltage on the basis of the write data and the write enable signal.
(5) The non-volatile memory according to any one of (2) to (4), in which:
the write control circuit is disposed in each of a plurality of columns;
the plurality of columns is divided into a predetermined number of sharing units that share a sense line; and
the reading circuit supplies the verification data via the sense line for each of the sharing units.
(6) The non-volatile memory according to any one of (1) to (5), in which
the write control circuit performs verification processing again after the write retry processing, and performs the write retry processing again in a case where the verification data and the write data do not match and the number of executions of the verification processing has not reached a predetermined upper limit.
(7) The non-volatile memory according to any one of (1) to (6), in which
the precharge circuit performs the precharge processing between the sense processing and the write retry processing.
(8) The non-volatile memory according to any one of (1) to (6), in which
the precharge circuit continues the precharge processing until the write retry processing ends.
(9) The non-volatile memory according to any one of (1) to (8), in which
the memory cell includes a transistor and a resistive element connected in series between the pair of signal lines.
(10) The non-volatile memory according to any one of (1) to (9), in which
a supply period of the power supply voltage during the write retry processing is longer than a supply period of the power supply voltage during the write processing.
(11) A semiconductor storage device including:
a memory cell inserted between a pair of signal lines;
a write control circuit that performs write processing of supplying a predetermined power supply voltage to one signal line corresponding to write data among the pair of signal lines, and write retry processing of bringing the pair of signal lines into a floating state in a case where verification data and the write data match and supplying the power supply voltage to the signal line in a case where the verification data and the write data do not match;
a reading circuit that performs sense processing of reading data from the memory cell after the write processing and supplying the data as the verification data to the write control circuit;
a precharge circuit that starts precharge processing of supplying an inhibition voltage different from a predetermined reference voltage to the pair of signal lines between the sense processing and the write retry processing; and
a memory controller that supplies the write data and causes the write processing to be executed.
(12) A non-volatile memory control method including:
a write procedure in which a write control circuit supplies a predetermined power supply voltage to one signal line corresponding to write data among a pair of signal lines having a memory cell inserted therebetween;
a write retry procedure in which a write control circuit supplies the power supply voltage to the signal line in a case where the verification data and the write data do not match;
a sense procedure in which a reading circuit reads data from the memory cell after the write processing and supplies the data as the verification data to the write control circuit; and
a precharge procedure in which a precharge circuit starts precharge processing of supplying an inhibition voltage different from a predetermined reference voltage to the pair of signal lines between the sense processing and the write retry processing.

### REFERENCE SIGNS LIST

100 Semiconductor storage device
110 Memory controller
200 Non-volatile memory
211 Interface
212 Address circuit
213 Column decoder
214 Memory control unit
215 Row decoder
216 Row driver
217 Column driver
218 Memory cell array
220 Memory cell
221 nMOS transistor
222 MTJ element
231 Word line
232 Data line
233 Source line
234 Bit line
235 Sense line
236 Enable signal line
310 Precharge circuit
311, 312 Precharge switch
313, 365, 366 logical product (AND) gate
314 logical sum (OR) gate
320 Power supply side write control circuit
321, 341 to 344, 351, 361 to 364 Inverter
322, 352 Selector
323, 324, 353, 354 Latch circuit
325, 326, 355, 356 Switch
327 Exclusive negative OR (XNOR) Gate
328 Exclusive OR (XOR) gate
330 Reading circuit
331 Sense amplifier
332 Sense switch
340 Write driver
345, 346 Negative AND (NAND) gate
350 ground side write control circuit
360 Column selector
12031 Imaging section

1. A non-volatile memory comprising:
a memory cell inserted between a pair of signal lines;
a write control circuit that performs write processing of supplying a predetermined power supply voltage to one signal line corresponding to write data among the pair of signal lines, and write retry processing of bringing the pair of signal lines into a floating state in a case where verification data and the write data match and supplying the power supply voltage to the signal line in a case where the verification data and the write data do not match;
a reading circuit that performs sense processing of reading data from the memory cell after the write processing and supplying the data as the verification data to the write control circuit; and
a precharge circuit that starts precharge processing of supplying an inhibition voltage different from a predetermined reference voltage to the pair of signal lines between the sense processing and the write retry processing.

2. The non-volatile memory according to claim 1, wherein:
the write control circuit includes a power supply side write control circuit and a ground side write control circuit;
the power supply side write control circuit includes
a first latch circuit that holds the write data,
a second latch circuit that holds either the verification data or inverted data obtained by inverting the write data, and
a write driver that causes the power supply voltage to be supplied to one of the pair of signal lines on a basis of data held in each of the first and second latch circuits; and
the ground side write control circuit includes a column selector that connects another of the pair of signal lines and the reference voltage.

3. The non-volatile memory according to claim 2, wherein
the ground side write control circuit includes:
a third latch circuit that holds the write data;
a fourth latch circuit that holds either the verification data or the inverted data; and
a column selector that connects the another and the reference voltage on a basis of data held in each of the third and fourth latch circuits.

4. The non-volatile memory according to claim 2, wherein
the write driver generates a predetermined write enable signal on a basis of the data, and
the ground side write control circuit includes
a third latch circuit that holds the write data, and
a column selector that connects the another and the reference voltage on a basis of the write data and the write enable signal.

5. The non-volatile memory according to claim 2, wherein:
the write control circuit is disposed in each of a plurality of columns;
the plurality of columns is divided into a predetermined number of sharing units that share a sense line; and
the reading circuit supplies the verification data via the sense line for each of the sharing units.

6. The non-volatile memory according to claim 1, wherein
the write control circuit performs verification processing again after the write retry processing, and performs the write retry processing again in a case where the verification data and the write data do not match and the number of executions of the verification processing has not reached a predetermined upper limit.

7. The non-volatile memory according to claim 1, wherein
the precharge circuit performs the precharge processing between the sense processing and the write retry processing.

8. The non-volatile memory according to claim 1, wherein
the precharge circuit continues the precharge processing until the write retry processing ends.

9. The non-volatile memory according to claim 1, wherein
the memory cell includes a transistor and a resistive element connected in series between the pair of signal lines.

10. The non-volatile memory according to claim 1, wherein
a supply period of the power supply voltage during the write retry processing is longer than a supply period of the power supply voltage during the write processing.

11. A semiconductor storage device comprising:
a memory cell inserted between a pair of signal lines;
a write control circuit that performs write processing of supplying a predetermined power supply voltage to one signal line corresponding to write data among the pair of signal lines, and write retry processing of bringing the pair of signal lines into a floating state in a case where verification data and the write data match and supplying the power supply voltage to the signal line in a case where the verification data and the write data do not match;
a reading circuit that performs sense processing of reading data from the memory cell after the write processing and supplying the data as the verification data to the write control circuit;
a precharge circuit that starts precharge processing of supplying an inhibition voltage different from a predetermined reference voltage to the pair of signal lines between the sense processing and the write retry processing; and
a memory controller that supplies the write data and causes the write processing to be executed.

12. A non-volatile memory control method comprising:
a write procedure in which a write control circuit supplies a predetermined power supply voltage to one signal line corresponding to write data among a pair of signal lines having a memory cell inserted therebetween;
a write retry procedure in which a write control circuit supplies the power supply voltage to the signal line in a case where the verification data and the write data do not match;
a sense procedure in which a reading circuit reads data from the memory cell after the write processing and supplies the data as the verification data to the write control circuit; and
a precharge procedure in which a precharge circuit starts precharge processing of supplying an inhibition voltage different from a predetermined reference voltage to the pair of signal lines between the sense processing and the write retry processing.
